(19) United States
(12) Patent Application Publication
(10) Pub. No.: US 2019/0033243 A1
(43) Pub. Date: Jan. 31, 2019

(54) OXIDE BARRIER COATED SEMICONDUCTOR GAS SENSORS

(71) Applicant: Apple Inc., Cupertino, CA (US)

(72) Inventors: Miaolei YAN, Santa Clara, CA (US); Roberto M. RIBEIRO, San Jose, CA (US); Richard YEH, Los Altos, CA (US)

(21) Appl. No.: 16/048,150

(22) Filed: Jul. 27, 2018

Related U.S. Application Data
(60) Provisional application No. 62/538,579, filed on Jul. 28, 2017.

(51) Int. Cl. G01N 27/12; B81B 3/00; B81B 7/00

(52) U.S. Cl. CPC G01N 27/125; B81B 2201/0214; B81B 7/0087; B81B 3/0089

(57) ABSTRACT

A miniature gas sensing device includes a silicon-based substrate embedded with one or more heating elements. One or more electrodes are disposed on the substrate, and a semiconductor gas sensing layer is deposited over the substrate including over the one or more electrodes. The semiconductor gas sensing layer includes sensing grains forming a porous matrix, and a nanometer-scale barrier oxide layer deposited over the sensing grains. The barrier layer separates gas adsorption from surfaces of the sensing grains, and enables electron tunneling based charge transfer process from the sensing grains to the barrier oxide layer. The barrier oxide layer enhances the sensor stability and promotes signal selectivity by favoring detection of strongly oxidizing and/or reducing gas species over less reactive gas species.

### CROSS-REFERENCE TO RELATED APPLICATIONS

This application claims the benefit of priority under 35 U.S.C. § 119 from U.S. Provisional Patent Application 62/538,579 filed Jul. 28, 2017, which is incorporated herein by reference in its entirety.

### TECHNICAL FIELD

The present description relates generally to sensors, and more particularly, to oxide barrier coated semiconductor gas sensors.

### BACKGROUND

Gas sensing technologies offer interesting value propositions for health and fitness monitoring, environmental crowdsourcing and pollution control. Miniature gas sensors can be tightly integrated with multiple consumer electronic platforms, such as mobile phones, smart watches and indoor air quality monitors. Metal oxide (MOX) based resistive gas sensors have been widely used and include several key benefits over competing technologies, such as reduced costs, small footprint, low power consumption and compatibility with silicon manufacturing processes. The MOX based gas sensors, however, may suffer from poor gas selectivity and poor stability.

The underlying principle of MOX gas sensors are based on the chemi-sorption of oxidizing and/or reducing gas species on the oxide surface, which is followed by a charge transfer process that can result in resistance changes of the MOX material. This approach typically cannot discriminate between different oxidizing gases such as ozone (O₃) and nitrogen oxide (NO₂) or different reducing gases such as hydrogen (H₂) or different volatile organic compounds (VOCs), thus resulting in poor gas sensing selectivity. Certain chemical species can poison the MOX material surfaces, which slows down or prevents further chemi-sorption reactions. This can change the material baseline resistance and/or sensitivity, thus causing poor sensor stability.

### BRIEF DESCRIPTION OF THE DRAWINGS

Certain features of the subject technology are set forth in the appended claims. However, for purposes of explanation, several embodiments of the subject technology are set forth in the following figures.

FIGS. 1A-1B are schematic diagrams illustrating an example of an oxide barrier coated semiconductor gas sensor and a sensor grain, in accordance with one or more aspects of the subject technology.

FIGS. 2A-2B are flow diagrams illustrating methods of preparing an oxide barrier coated semiconductor gas sensor, in accordance with one or more aspects of the subject technology.

FIG. 3 is a table illustrating characteristics of various deposition methods for preparing an oxide barrier coated semiconductor gas sensor, in accordance with one or more aspects of the subject technology.

FIG. 4 is a flow diagram illustrating a method of providing an oxide barrier coated semiconductor gas sensor, in accordance with one or more aspects of the subject technology.

FIG. 5 is a block diagram illustrating an example wireless communication device, within which a gas sensor of the subject technology is implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology is not limited to the specific details set forth herein and may be practiced without one or more of the specific details. In some instances, structures and components are shown in block diagram form in order to avoid obscuring the concepts of the subject technology.

In one or more aspects of the subject technology, solutions for improving gas sensing selectivity and enhancing long term stability of miniature gas sensors are provided. The subject technology is directed to deposition of an inert barrier oxide layer on the active sensing material surfaces of the gas sensor. The inert barrier oxide layer of the subject technology limits gas chemisorption to the barrier layer surface instead of the sensing layer surface of the gas sensor. The charge transfer process is based on “electron tunneling” effects, the probability of which depends on the oxidizing and/or reducing potential of the gas species relative to the sensing grains (among other parameters). Thus signals from strongly oxidizing and strongly reducing gas species are favored over less reactive gas species, resulting in enhanced gas sensing selectivity.

The disclosed solution also includes the benefits of increasing the long term stability and extending the lifetime of the subject gas sensors, by preventing poisoning chemical species from coming into direct contact with the sensing layer surface.

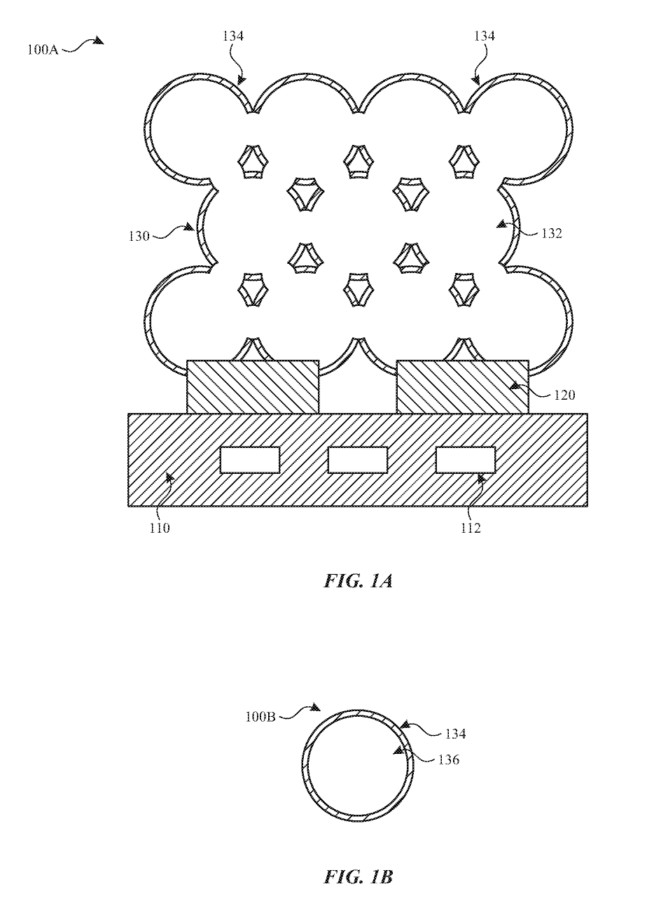

FIGS. 1A-1B are schematic diagrams illustrating an example of an oxide barrier coated semiconductor gas sensor 100A and a sensor grain 100B, in accordance with one or more aspects of the subject technology. The oxide barrier coated semiconductor gas sensor 100A (hereinafter “gas sensor 100A”) includes a substrate 110, multiple heating elements 112, one or more electrodes 120 and a semiconductor gas sensing layer 130. The semiconductor gas sensing layer 130 is deposited over the substrate 110 and the electrodes 120. The semiconductor gas sensing layer 130 includes a porous matrix 132 of sensing grains and a nanometer-scale barrier layer 134 (hereinafter “barrier layer 134”) deposited over the sensing grains. An example structure of the sensor grain 100B, as shown in FIG. 1B, depicts the barrier layer 134 and a metal oxide sensing grain 136 (hereinafter “sensing grain 136”). In some implementations, the thickness of the barrier layer 134 is within a range of about 5-100 nm.

In one or more implementations, the barrier layer 134 is a conformal and uniform layer of a metal oxide or metal nitride material. Examples of materials used for barrier layer 134 include, but are not limited to, silicon dioxide (SiO₂), silicon nitride (Si₃N₄), aluminum oxide (Al₂O₃), aluminum nitride (AlN), gallium oxide (Ga₂O₃), gallium nitride (GaN), zirconium oxide (ZrO₂), cerium oxide (CeO₂), or a mixture thereof. In some implementations, the sensor grain 100B forming the porous matrix 132 includes metal oxide semiconductor material such as tin oxide (SnO₂), tungsten oxide (WO₃), indium oxide (In₂O₃), titanium oxide (TiO₂), zinc oxide (ZnO) or a combination thereof. The list of metal oxide semiconductor material that can be used in the sensor grain 100B may not be limited to the above list and may include other materials, in some implementations.

The barrier layer 134 prevents direct contact between the gas species and the surfaces of the sensing grains 136. In other words, the gas species get chemisorbed by the barrier layer 134 before reaching the sensing grains 136. The chemisorption of the target gas within the barrier layer 134 can result in charge (e.g., electrons) generation or trapping in the barrier layer 134. The charge transfer from the barrier layer 134 to the sensing grain 136 can be based on electron tunneling effects between the barrier layer 134 and the sensing grain 136. The transferred charges between the barrier layer 134 to the sensing grain 136 is the cause of resistance change of the gas sensing layer 130, which is converted to a detector signal by the electrodes 120. The transfer of electrons from the barrier layer 134 to the sensing grain 136 causes the resistance of the gas sensing layer 130 to decrease. Whereas, the transfer of electrons from the sensing grain 136 to the barrier layer 134 causes the resistance of the gas sensing layer 130 to increase, this happens when the chemisorption of the target gas in the barrier layer 134 results in holes that have tendency to be filled with electron transfer from the sensing grain 136 to the barrier layer 134.

The amount of electron tunneling depends on the electrochemical potential of the target gas. Thus, a strongly oxidizing gas (e.g., O₃) and a strongly reducing gas (e.g., H₂) are favored over less reactive gases such as volatile organic compounds (VOCs). This is the basis of the gas selectivity of the subject miniature gas sensor.

Chemical poisoning and deactivation of the sensor materials in metal oxide sensors can cause premature device failures that may pose challenges to their mass market adoption. Various chemical species from the environment, including siloxanes, sulfates, chlorides and phosphates have been identified as high-risk poisons. In addition, humidity (e.g., water vapor) can be a major interfering species that can cause metal oxide sensor accuracy shifts, also known as baseline or sensitivity drifts. In one or more aspects, the barrier layer 134 protects the sensing grain 136 from such chemical species that can adversely affect the lifetime or accuracy of the sensing layer 130.

The substrate 110 is a silicon-based substrate and can be silicon substrates made of a silicon wafer. The heating elements 112 are micro electromechanical system (MEMS) hotplates and can include tungsten, which is compatible with complementary metal-oxide semiconductor (CMOS) process and has a high melting point (e.g., 3422° C.), although other suitable metals may be used. The heating elements 112 can be controlled (e.g., by a microcontroller or a general processor) and can be used to regulate the temperature of the gas sensing layer 130. For example, the temperature of the gas sensing layer 130 may be set to nominal temperature (e.g., within a range of about 250-600° C.) by the heating elements 112. In some aspects, the microcontroller or the general processor can be a processor of a host device within which the gas sensor 100A is integrated. In some aspects, the heating elements 112 can be used to regenerate the sensing capabilities of the gas sensing layer 130.

Miniature gas sensors such as the gas sensor 100A of the subject technology represent a technology category that could enable upcoming features and/or products in applications such as environmental and health monitoring, smart homes, internet of things (IoT), and a number of other applications.

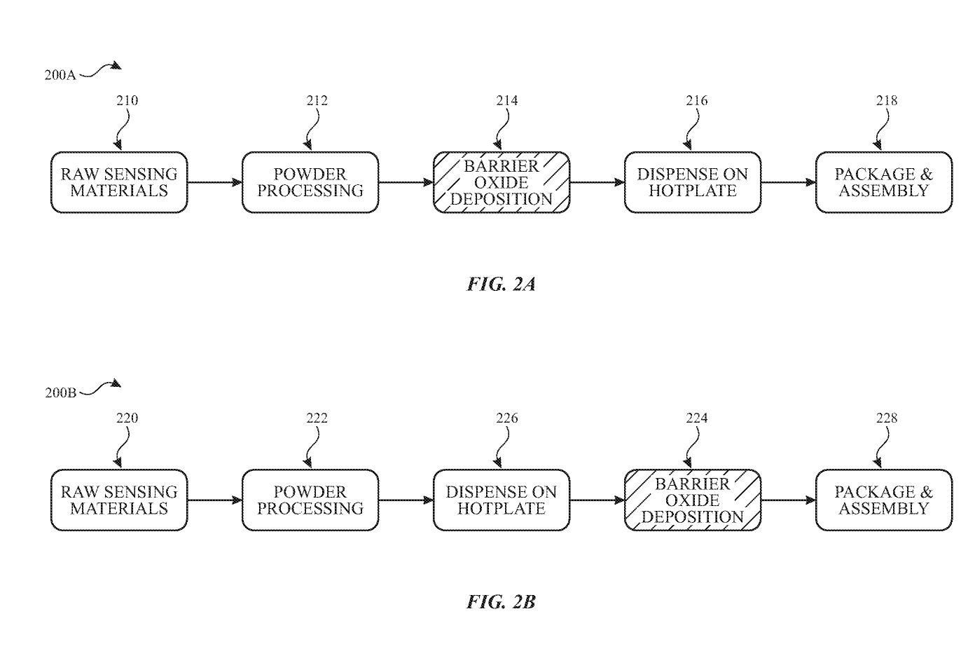

FIGS. 2A-2B are flow diagrams illustrating methods 200A and 200B of preparing an oxide barrier coated semiconductor gas sensor, in accordance with one or more aspects of the subject technology. The method 200A shown in FIG. 2A begins with an operation block 210, where raw sensing material are prepared. In some aspects, the raw sensing material can include metal oxide semiconductor material such as tin oxide (SnO₂), tungsten oxide (WO₃), indium oxide (In₂O₃), titanium oxide (TiO₂), zinc oxide (ZnO) or a combination thereof. At an operation block 212, the raw metal oxide semiconductor material is processed (e.g., crushed or ground) to be converted to a powder. The powder includes the sensing grains 136 of FIG. 1B. The next operation block 214 is a barrier oxide deposition process, in which the barrier layer 134 is formed (deposited) on the sensing grains 136.

The deposition of the barrier layer 134 can be performed using known atomic layer deposition (ALD), physical vapor deposition (PVD) or chemical vapor deposition (CVD) techniques. Each of these techniques has its own characteristics in terms of the deposited films as will be discussed below. The result of deposition of the barrier layer 134 is a porous matrix 132 of the sensing grain 136 that form the gas sensing layer 130 of FIG. 1. In the gas sensing layer 130, the sensing grains are attached to one another at two or more contact points (junctions) and the barrier layer 134 covers the surfaces of sensing grain 136 and their junctions, as shown in FIG. 1A.

At operation block 216, the gas sensing layer 130, formed in the operation block 215, is dispensed over the substrate 110 of FIG. 1A including the heating elements 112 of FIG. 1A (e.g., hotplate) and the electrodes 120, using known dispensing techniques. Finally, at the operation block 218, the packaging and assembly of the miniature gas sensor, for example, in a host device such as a smart phone, a smart watch or another host device take place. The miniature gas sensor of the subject technology can operate in an environment of the host device and can use processing capabilities of the host device to calibrate miniature gas sensor and read the sensor signals.

The operation blocks 220, 222, 224, 226 and 228 of the method 200B shown in FIG. 2B are similar to respective operation blocks 210, 212, 214, 216 and 218 of the method 200A shown in FIG. 2A, except that the operation block 226 is performed before the operation block 224. In the method 200B, the metal oxide semiconductor powder including the sensing grains 136, prepared in the operation block 222, is dispensed over the hotplate (e.g., the substrate 110 including the heating elements 112 and the electrodes 120) as discussed with respect to the operation block 216. The amount of metal oxide semiconductor powder dispensed over the hotplate depends on the desired thickness of the gas sensing layer 130. At the subsequent operation block 224, the hotplate covered with the metal oxide semiconductor powder is transferred to a deposition machine such as an ALD, a PVD, or a CVD machine for barrier oxide deposition. The packaging and assembly operation block 228 is the same as described above with respect to the packaging and assembly operation block 218. An advantage of the method 200B is a better cohesion of the gas sensing layer 130 to the hotplate, as the sensing layer 130 is formed hand-free on the hotplate at a presumably higher temperature inside a deposition chamber of the ALD, PVD or CVD machine.

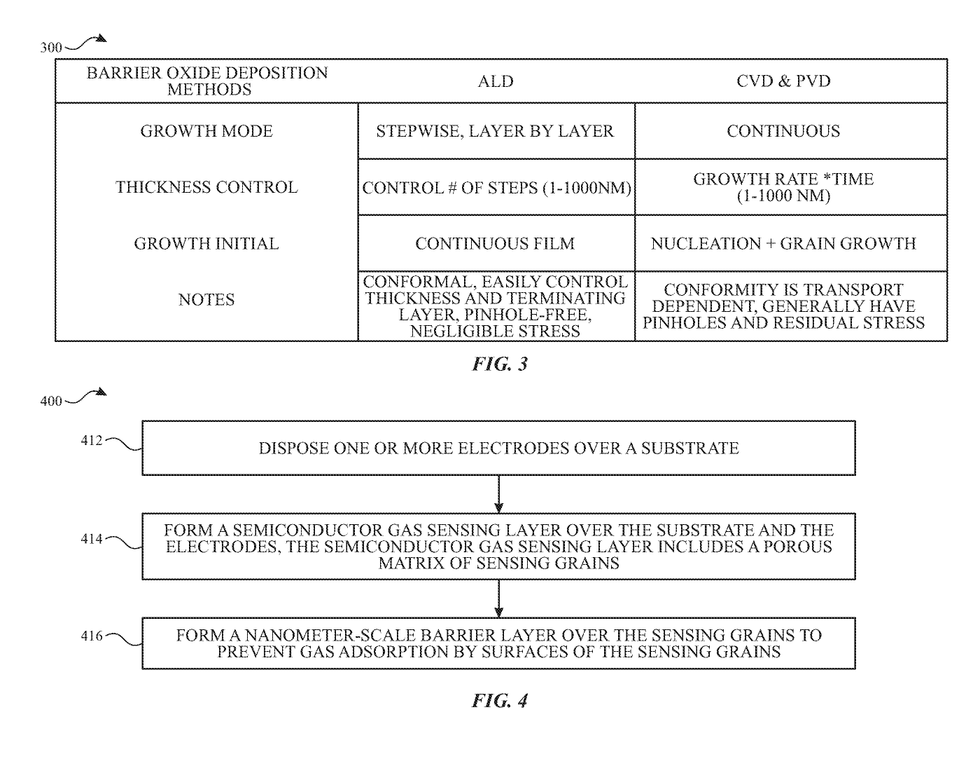

FIG. 3 is a Table 300 illustrating characteristics of various deposition methods for preparing an oxide barrier coated semiconductor gas sensor, in accordance with one or more aspects of the subject technology. In the Table 300, characteristics such as growth mode, thickness control and growth initiation for ALD and CVD or PVD deposition techniques are shown. For example, the growth mode in the ALD technique is layer by layer (stepwise), whereas in CVD or PVD the growth is continuous. The thickness control in ALD is by control of the number of steps (layers) and a deposition layer with a thickness within a range of 1-1000 nm can be achieved. In the CVD or PVD, on the other hand, thickness control (e.g., within a range of 1-1000 nm) can be achieved by deposition time. The longer the deposition time, the thicker the deposited layer. In ALD, the film growth is initiated by forming a continuous film, whereas in CVD and PVD techniques, the film growth is initiated by nucleation and grain growth. Further, an ALD grown film is conformal and control of the film thickness and the terminating layer is relatively easy. The ALD grown film is generally pin-hole free and has negligible stress. In the CVD or PVD grown films, conformity is transport dependent and the film may generally have pinholes and residual stress.

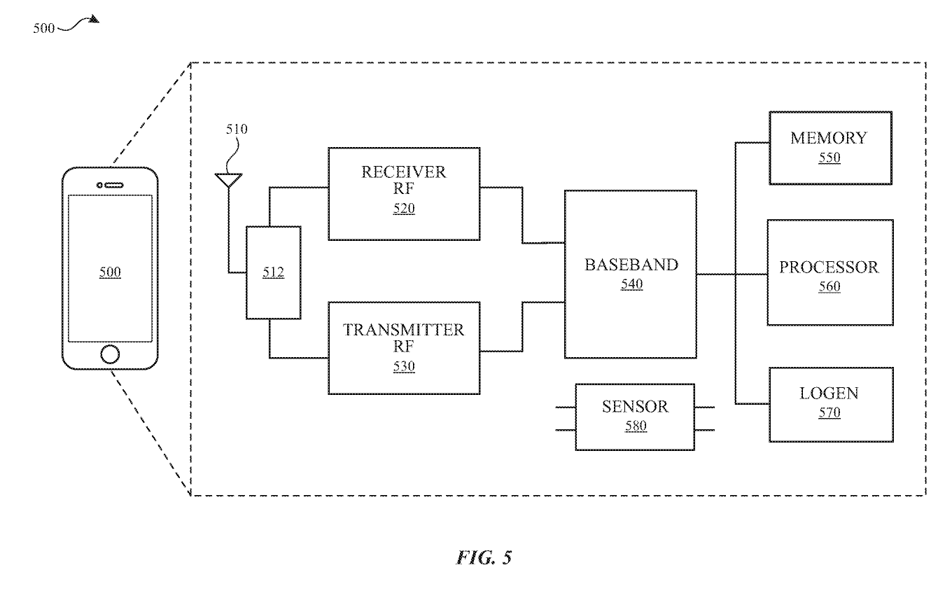

FIG. 4 is a flow diagram illustrating a method 400 of providing an oxide barrier coated semiconductor gas sensor (e.g., 100A of FIG. 1A), in accordance with one or more aspects of the subject technology. The method 400 begins with disposing one or more electrodes (e.g., 120 of FIG. 1A) over a substrate (e.g., 110 of FIG. 1A) such as a silicon-based substrate (410). A semiconductor gas sensing layer (e.g., 130 of FIG. 1A) is deposited over the silicon-based substrate and the electrodes (420). The semiconductor gas sensing layer includes a porous matrix (e.g., 132 of FIG. 1A) of sensing grains (e.g., 136 of FIG. 1B). A nanometer-scale barrier layer (e.g., 134 of FIGS. 1A and 1B) is deposited over the sensing grains to prevent gas adsorption by surfaces of the sensing grains (430).

FIG. 5 is a block diagram illustrating an example wireless communication device, within which a gas sensor of the subject technology is implemented. Examples of the wireless communication device 500 include a smart phone, a smart watch, personal digital assistant (PDA) or other handheld communication devices that can be host device for the miniature oxide barrier coated semiconductor gas sensor of the subject technology. The wireless communication device 500 may comprise a radio-frequency (RF) antenna 510, a receiver 520, a transmitter 530, a baseband processing module 540, a memory 550, a processor 560, a local oscillator generator (LOGEN) 570 and a sensor 580. In various embodiments of the subject technology, one or more of the blocks represented in FIG. 5 may be integrated on one or more semiconductor substrates. For example, the blocks 520-570 may be realized in a single chip or a single system on a chip, or may be realized in a multi-chip chipset.

The receiver 520 may comprise suitable logic circuitry and/or code that may be operable to receive and process signals from the RF antenna 510. The receiver 520 may, for example, be operable to amplify and/or down-convert received wireless signals. In various embodiments of the subject technology, the receiver 520 may be operable to cancel noise in received signals and may be linear over a wide range of frequencies. In this manner, the receiver 520 may be suitable for receiving signals in accordance with a variety of wireless standards, Wi-Fi, WiMAX, Bluetooth, and various cellular standards. In various embodiments of the subject technology, the receiver 520 may not require any SAW filters and few or no off-chip discrete components such as large capacitors and inductors.

The transmitter 530 may comprise suitable logic circuitry and/or code that may be operable to process and transmit signals from the RF antenna 510. The transmitter 530 may, for example, be operable to up-convert baseband signals to RF signals and amplify RF signals. In various embodiments of the subject technology, the transmitter 530 may be operable to up-convert and amplify baseband signals processed in accordance with a variety of wireless standards. Examples of such standards may include Wi-Fi, WiMAX, Bluetooth, and various cellular standards. In various embodiments of the subject technology, the transmitter 530 may be operable to provide signals for further amplification by one or more power amplifiers.

The duplexer 512 may provide isolation in the transmit band to avoid saturation of the receiver 520 or damaging parts of the receiver 520, and to relax one or more design requirements of the receiver 520. Furthermore, the duplexer 512 may attenuate the noise in the receive band. The duplexer may be operable in multiple frequency bands of various wireless standards.

The baseband processing module 540 may comprise suitable logic, circuitry, interfaces, and/or code that may be operable to perform processing of baseband signals. The baseband processing module 540 may, for example, analyze received signals and generate control and/or feedback signals for configuring various components of the wireless communication device 500, such as the receiver 520. The baseband processing module 540 may be operable to encode, decode, transcode, modulate, demodulate, encrypt, decrypt, scramble, descramble, and/or otherwise process data in accordance with one or more wireless standards.

The processor 560 may comprise suitable logic, circuitry, and/or code that may enable processing data and/or controlling operations of the wireless communication device 500. In this regard, the processor 560 may be enabled to provide control signals to various other portions of the wireless communication device 500. The processor 560 may also control transfers of data between various portions of the wireless communication device 500. Additionally, the processor 560 may enable implementation of an operating system or otherwise execute code to manage operations of the wireless communication device 500. In some aspects, the processor 560 may process the detector signals generated by the electrodes (e.g., 120 of FIG. 1A) of the sensor 580 (e.g., the miniature gas sensor 100A of FIG. 1A) that is integrated with the wireless communication device 500.

The memory 550 may comprise suitable logic, circuitry, and/or code that may enable storage of various types of information such as received data, generated data, code, and/or configuration information. The memory 550 may comprise, for example, RAM, ROM, flash, and/or magnetic storage. In various embodiment of the subject technology, information stored in the memory 550 may be utilized for configuring the receiver 520 and/or the baseband processing module 540.

The local oscillator generator (LOGEN) 570 may comprise suitable logic, circuitry, interfaces, and/or code that may be operable to generate one or more oscillating signals of one or more frequencies. The LOGEN 570 may be operable to generate digital and/or analog signals. In this manner, the LOGEN 570 may be operable to generate one or more clock signals and/or sinusoidal signals. Characteristics of the oscillating signals such as the frequency and duty cycle may be determined based on one or more control signals from, for example, the processor 560 and/or the baseband processing module 540.

In operation, the processor 560 may configure the various components of the wireless communication device 500 based on a wireless standard according to which it is desired to receive signals. Wireless signals may be received via the RF antenna 510 and amplified and down-converted by the receiver 520. The baseband processing module 540 may perform noise estimation and/or noise cancellation, decoding, and/or demodulation of the baseband signals. In this manner, information in the received signal may be recovered and utilized appropriately. For example, the information may be audio and/or video to be presented to a user of the wireless communication device, data to be stored to the memory 550, and/or information affecting and/or enabling operation of the wireless communication device 500. The baseband processing module 540 may modulate, encode and perform other processing on audio, video, and/or control signals to be transmitted by the transmitter 530 in accordance with various wireless standards.

In some aspects, the sensor 580 is an oxide barrier coated semiconductor miniature gas sensor (e.g., 100A of FIG. 1A) and may be prepared using the method 400 of FIG. 4, as described above.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

The predicate words “configured to”, “operable to”, and “programmed to” do not imply any particular tangible or intangible modification of a subject, but, rather, are intended to be used interchangeably. For example, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

A phrase such as an “aspect” does not imply that such aspect is essential to the subject technology or that such aspect applies to all configurations of the subject technology. A disclosure relating to an aspect may apply to all configurations, or one or more configurations. A phrase such as an aspect may refer to one or more aspects and vice versa. A phrase such as a “configuration” does not imply that such configuration is essential to the subject technology or that such configuration applies to all configurations of the subject technology. A disclosure relating to a configuration may apply to all configurations, or one or more configurations. A phrase such as a configuration may refer to one or more configurations and vice versa.

The word “example” is used herein to mean “serving as an example or illustration.” Any aspect or design described herein as “example” is not necessarily to be construed as preferred or advantageous over other aspects or designs.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.” Furthermore, to the extent that the term “include,” “have,” or the like is used in the description or the claims, such term is intended to be inclusive in a manner similar to the term “comprise” as “comprise” is interpreted when employed as a transitional word in a claim.

What is claimed is:

1. A miniature gas sensing device, the device comprising:
a silicon-based substrate;
one or more electrodes disposed on the silicon-based substrate;
a semiconductor gas sensing layer deposited over the silicon-based substrate including the one or more electrodes, the semiconductor gas sensing layer comprising sensing grains forming a porous matrix; and
a nanometer-scale barrier layer deposited over the sensing grains and configured to separate gas adsorption from the surfaces of the sensing grains.

2. The device of claim 1, wherein a thickness of the nanometer-scale barrier layer is within a range of about 5-500 nm.

3. The device of claim 1, wherein the nanometer-scale barrier layer is configured to chemisorb gas species and cause a change of resistance of the semiconductor gas sensing layer through a charge transfer process.

4. The device of claim 1, wherein the nanometer-scale barrier layer is configured to enable an electron tunneling charge transfer process between the nanometer-scale barrier layer and the semiconductor gas sensing layer.

5. The device of claim 1, wherein the nanometer-scale barrier layer is configured to selectively detect gas spices with strong oxidizing or reducing potentials, by enabling electron tunneling based charge transfer process from the sensing material grain to the surface of the barrier coating layer.

6. The device of claim 1, wherein the nanometer-scale barrier layer comprises a conformal and uniform layer of a metal oxide or a metal nitride material including at least one of a silicon oxide (SiO₂), a silicon nitride (Si₃N₄), an aluminum oxide (Al₂O₃), an aluminum nitride (AlN), a gallium oxide (Ga₂O₃), a gallium nitride (GaN), a zirconium oxide (ZrO₂) and a cerium oxide (CeO₂) material.

7. The device of claim 1, wherein the sensing grains forming the porous matrix comprise a metal oxide semiconductor material including at least one of a tin oxide (SnO₂), a tungsten oxide (WO₃), an indium oxide (In₂O₃), titanium oxide (TiO₂) and zinc oxide (ZnO).

8. The device of claim 1, wherein the silicon-based substrate is embedded with one or more heating elements including micro electromechanical system (MEMS) hotplates.

9. The device of claim 8, wherein the MEMS hotplates are configured to regulate a temperature of the semiconductor gas sensing layer.

10. The device of claim 1, wherein the nanometer-scale barrier layer is configured to protect the sensing grains from chemical species that cause either permanently poisoning of the sensing grain or temporarily inducing sensing behavior drifts.

11. The device of claim 1, wherein the nanometer-scale barrier layer is configured to enable selective detection of gas species with higher oxidizing or reducing potential.

12. A miniature gas sensing device, the device comprising:
a substrate including one or more heating elements;
one or more electrodes;
a semiconductor gas sensing layer deposited over the substrate and the one or more electrodes, the semiconductor gas sensing layer comprising a porous matrix of metal oxide sensing grains; and
a nanometer-scale barrier layer deposited over the metal oxide sensing grains,
wherein:
the one or more electrodes are configured to generate a signal based on a resistance change of the semiconductor gas sensing layer due to exposure to a target gas, and
the nanometer-scale barrier layer is configured to separate target gas adsorption from surfaces of the metal oxide sensing grains.

13. The device of claim 12, wherein a thickness of the nanometer-scale barrier layer is within a range of about 5-500 nm.

14. The device of claim 12, wherein the nanometer-scale barrier layer is configured to chemisorb target gas species and to enable electron transfer between the nanometer-scale barrier layer and the metal oxide sensing grains.

15. The device of claim 12, wherein the substrate comprises a silicon-based material, and wherein the substrate comprises silicon.

16. The device of claim 12, wherein the metal oxide sensing grains comprise grains of a metal oxide semiconductor material, and wherein the metal oxide semiconductor material includes at least one of a tin oxide (SnO₂), a tungsten oxide (WO₃), an indium oxide (In₂O₃), titanium oxide (TiO₂) and zinc oxide (ZnO).

17. The device of claim 12, wherein the nanometer-scale barrier layer is configured to enable selective detection of gas species with higher oxidizing or reducing potential.

18. The device of claim 12, the one or more heating elements comprise micro electromechanical system (MEMS) hotplates and are configured to regulate a temperature of the semiconductor gas sensing layer.

19. A system comprising:
a host device; and
a miniature gas sensor integrated within the host device, the miniature gas sensor comprising:
a silicon-based substrate;
one or more electrodes;
a semiconductor gas sensing layer formed over the silicon-based substrate and in contact with the one or more electrodes, the semiconductor gas sensing layer comprising a porous matrix of sensing grains; and
a nanometer-scale barrier layer deposited over the sensing grains and configured to prevent gas species including a target gas from directly contacting surfaces of the sensing grains.

20. The system of claim 19, wherein the host device comprises a smart phone or a smart watch, wherein a thickness of the nanometer-scale barrier layer is within a range of about 5-500 nm, and wherein the one or more electrodes are configured to generate a signal based on a change of resistance of the semiconductor gas sensing layer, and wherein a processor of the host device is configured to process the signal.
